(19) United States
(12) Patent Application Publication
(10) Pub. No.: US 2024/0126344 A1
(43) Pub. Date: Apr. 18, 2024

(54) DISPLAY APPARATUS

(71) Applicant: SAMSUNG DISPLAY CO., LTD., YONGIN-SI (KR)

(72) Inventors: Youngdo Kim, Yongin-si (KR); Sunghoon Kim, Yongin-si (KR); Sungguk An, Yongin-si (KR); Soojung Lee, Yongin-si (KR); Chlho Jeong, Yongin-si (KR)

(21) Appl. No.: 18/488,462

(22) Filed: Oct. 17, 2023

(30) Foreign Application Priority Data
Oct. 17, 2022 (KR) 10-2022-0133612

(51) Int. Cl. G06F 1/16; G06F 1/20

(52) U.S. Cl. CPC G06F 1/1656; G06F 1/1616; G06F 1/1635; G06F 1/1643; G06F 1/203

(57) ABSTRACT

A display apparatus includes a first display area, a second display area, and a folding area between the first display area and the second display area, a display panel, a first support member disposed under the display panel, and a battery disposed under the first support member.

### CROSS-REFERENCE TO RELATED APPLICATION

This application claims priority under 35 U.S.C. § 119 from Korean Patent Application No. 10-2022-0133612, filed on Oct. 17, 2022 in the Korean Intellectual Property Office, the contents of which are herein incorporated by reference in their entirety.

### TECHNICAL FIELD

One or more embodiments are directed to a display apparatus.

### DISCUSSION OF THE RELATED ART

Mobility-based electronic devices are widely used. Recently, tablet personal computers (PCs), in addition to small electronic devices such as mobile phones, have become widely used as mobile electronic devices.

A mobile electronic device includes a display apparatus that provides visual information such as an image to a user, to support various functions. Recently, as other components for driving a display apparatus have been miniaturized, the proportion of the display apparatus in an electronic device has gradually increased, and a structure that can be bent from a flat state to a curved state has been developed.

### SUMMARY

One or more embodiments include a display apparatus in which performance is increased by locating a battery in a lower structure of the display apparatus.

According to one or more embodiments, a display apparatus includes a first display area, a second display area, and a foldable area disposed between the first display area and the second display area, a display panel, a first support member disposed under the display panel, and a battery disposed under the first support member.

The first support member may include a first portion that at least partially overlaps the first display area, and a second portion that at least partially overlaps the second display area.

The first support member may further include a foldable structure disposed between the first portion and the second portion.

The battery may include a first battery that at least partially overlaps the first portion and a second battery that at least partially overlaps the second portion.

The display apparatus may further include a heat dissipating layer disposed between the first support member and the battery.

The heat dissipating layer may include one of copper or graphite.

An adhesive layer may be disposed over or under the foldable structure.

The adhesive layer may include polyurethane.

The battery may be an auxiliary power supply.

The battery may be flexible.

The battery may include a physically crosslinked organogel that is an active material or a separator of a positive electrode and a negative electrode of the battery.

The battery may be formed by using a printing method.

The first support member may include one of stainless steel, carbon fiber reinforced plastic, or glass fiber reinforced plastic.

The first support member may include one of an aluminum alloy, a titanium alloy, or a magnesium alloy.

The display apparatus may further include a second support member disposed between the first support member and the battery.

The display apparatus may further include a digitizer disposed between the first support member and the battery.

The digitizer may include a first digitizer that at least partially overlaps the first display area and a second digitizer that at least partially overlaps the second display area.

According to one or more embodiments, a rollable display apparatus includes a display panel, a support member disposed under the display panel, and a battery disposed under the support member. The battery may be integrally formed with a display module of the rollable display apparatus.

The support member may include a folding structure.

According to one or more embodiments, a display apparatus a display panel; a first support member disposed under the display panel, wherein the first support member comprises a first portion, a second portion, and a foldable structure disposed between the first portion and the second portion; and a battery disposed under the first support member, wherein the battery comprises a first battery that at least partially overlaps the first portion and a second battery that at least partially overlaps the second portion.

### BRIEF DESCRIPTION OF THE DRAWINGS

FIG. 1 is a perspective view of a display apparatus, according to an embodiment.

FIG. 2 is a cross-sectional view taken along a line I-I′ of a display apparatus of FIG. 1, according to an embodiment.

FIG. 3 is a cross-sectional view of a cover window of a display apparatus, according to an embodiment.

FIGS. 4 and 5 are cross-sectional views of a display apparatus, according to embodiments.

FIG. 6 is a cross-sectional view of a digitizer of FIG. 5.

FIG. 7 is a cross-sectional view of a rollable display apparatus, according to an embodiment.

FIG. 8 is a plan view of a display panel of a display apparatus, according to an embodiment.

FIG. 9 is a cross-sectional view taken along a line II-II′ of FIG. 8.

FIG. 10 is a cross-sectional view of a display apparatus, according to an embodiment.

### DETAILED DESCRIPTION

Reference will now be made in detail to embodiments, examples of which are illustrated in the accompanying drawings, wherein like reference numerals may refer to like elements throughout.

It will be further understood that, when a layer, region, or component is referred to as being “on” another layer, region, or component, it may be directly on the other layer, region, or component, or may be indirectly on the other layer, region, or component with intervening layers, regions, or components therebetween.

It will be understood that when a layer, an area, or an element is referred to as being “connected” to another layer, area, or element, it may be “directly connected” to the other layer, area, or element and/or may be “indirectly connected” to the other layer, area, or element with other layers, areas, or elements interposed therebetween

The x-axis, the y-axis and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another.

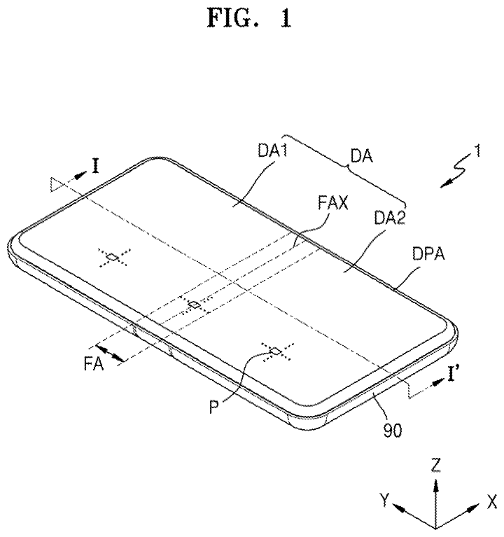

FIG. 1 is a perspective view of a display apparatus 1, according to an embodiment. The display apparatus 1 has a rectangular shape. For example, the display apparatus 1 has a rectangular planar shape that has a short side in a first direction, such as an x direction, and a long side in a second direction, such as a y direction. A corner where the short side in the first direction, such as the x direction, and the long side in the second direction, such as the y direction, meet each other may be rounded with a predetermined curvature or have a right angle. A planar shape of the display apparatus 1 is not limited to a rectangular shape, and may be any of other shapes, such as another polygonal shape, an elliptical shape, or an irregular shape.

In an embodiment, the display apparatus 1 includes a display area DA and a peripheral area DPA. The display area DA is where pixels P are disposed to display an image, and the peripheral area DPA is where pixels are not disposed. The peripheral area DPA surrounds at least a part of the display area DA. The display area DA includes a first display area DA1, a second display area DA2, and a foldable area FA. The first display area DA1 and the second display area DA2 are disposed on both sides of the foldable area FA. The display apparatus 1 can be folded around the foldable area FA.

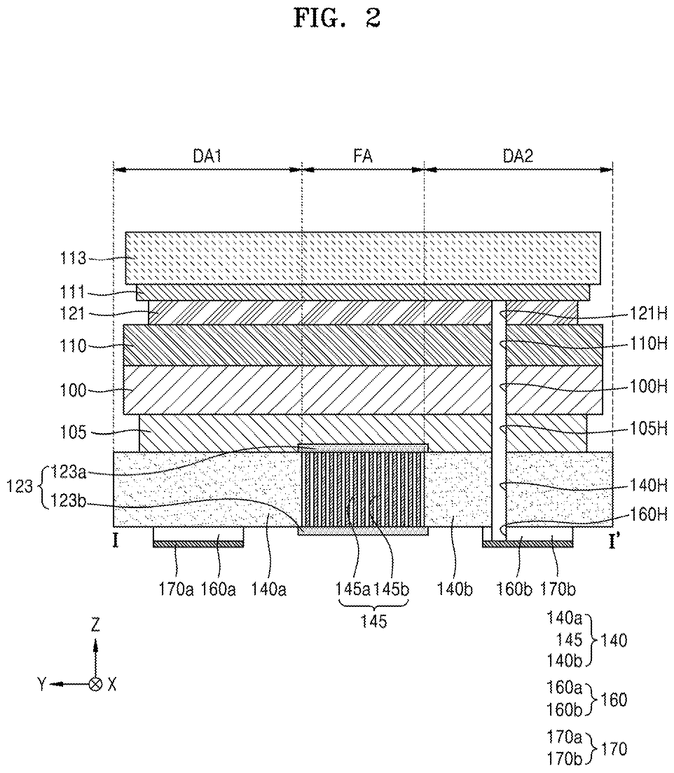

The display apparatus 1 can be provided in various ways. In an embodiment, a shape of the display apparatus 1 is not variable. In an embodiment, at least a portion of the display apparatus 1 can be folded. When the display apparatus 1 is folded, the display apparatus 1 may be an in-folding type display in which the display areas DA of a display panel 100 (see FIG. 2) face each other, or may be an out-folding type display in which display areas of the display panel 100 are externally exposed and do not face each other. For convenience of explanation, the following will be described assuming that the display apparatus 1 is an in-folding type display.

In an embodiment, the display apparatus 1 can be folded around a folding axis FAX. When the display apparatus 1 is folded around the folding axis FAX, a size of the display area DA decreases, and when the display apparatus 1 is fully unfolded, the display area DA has a flat surface to display an image, thereby making it possible to implement a large screen.

The display panel 100 (see FIG. 2) is a light-emitting display panel that includes a light-emitting element. For example, the display panel 100 may be one of an organic light-emitting display panel that uses an organic light-emitting diode that includes an organic emission layer, a micro light-emitting diode display panel that uses a micro light-emitting diode (LED), a quantum dot light-emitting display panel that uses a quantum dot light-emitting diode that includes a quantum dot emission layer, or an inorganic light-emitting display panel that uses an inorganic light-emitting element that includes an inorganic semiconductor.

The display panel 100 may be a rigid display panel 100 that is not easily bent, or a flexible display panel 100 that is easily bent, folded, or rolled. For example, the display panel 100 may be one of a foldable display panel 100 that can be folded and unfolded, a curved display panel 100 that has a curved display surface, a bent display panel 100 in which a portion other than a display surface is bent, a rollable display panel 100 that can be rolled or unrolled, or a stretchable display panel 100 that can be stretched.

The display panel 100 may be a transparent display panel 100 in which an object or a background disposed on a bottom surface of the display panel 100 is visible through a top surface of the display panel 100. Alternatively, the display panel 100 may be a reflective display panel 100 in which an object or a background of a top surface of the display panel 100 is reflected.

A lower cover 90 is disposed under the display panel 100. The lower cover 90 forms an outer appearance of a bottom surface of the display apparatus 1. The lower cover 90 includes plastic, metal, or both plastic and metal.

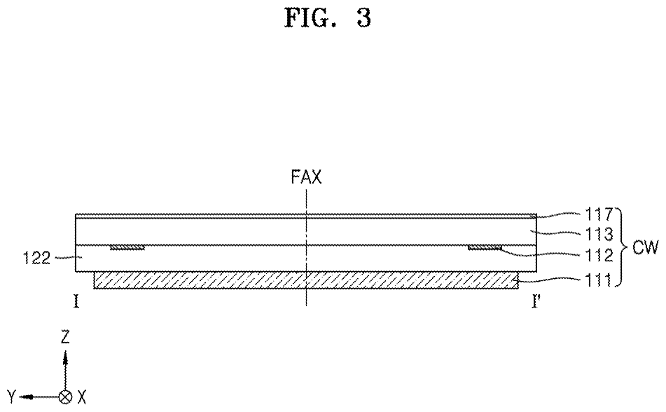

FIG. 2 is a cross-sectional view taken along a line I-I′ of the display apparatus 1 of FIG. 1, according to an embodiment. FIG. 3 is a cross-sectional view of a cover window CW of the display apparatus 1, according to an embodiment.

Referring to FIGS. 2 and 3, in an embodiment, the display apparatus 1 includes a window protection member 113, a window 111, a first adhesive layer 121, a polarizing film 110, the display panel 100, a planarization film 105, a first support member 140, a heat dissipating layer 160, and a battery 170. Although the first adhesive layer 121 is disposed between the polarizing film 110 and the window 111 and a second adhesive layer 122 is disposed between the window 111 and the window protection member 113 in FIGS. 2 and 3, embodiments of the disclosure are not necessarily limited thereto.

The polarizing film 110 is disposed on the display panel 100. The polarizing film 110 is attached to the display panel 100 and modulates or increases optical characteristics. For example, the polarizing film 110 reduces reflection of external light and increases the display quality of the display apparatus 1.

The window 111 is disposed on the polarizing film 110. The window 111 is adhered to a top surface of the polarizing film 110 through the first adhesive layer 121. For example, the first adhesive layer 121 is a pressure sensitive adhesive (PSA). However, embodiments of the disclosure are not necessarily limited thereto.

In addition, a protection member may be disposed on the display panel 100. The protection member is disposed on the display panel 100 and protects the display panel 100 from external impacts.

In an embodiment, the window 111 and the window protection member 113 are disposed on the display panel 100 and the polarizing film 110. However, embodiments of the disclosure are not necessarily limited thereto. In an embodiment, the window 111 and the window protection member 113 are disposed on the display panel 100 and the polarizing film 110, and the second adhesive layer 122 and an opaque layer 112 are additionally disposed between the window 111 and the window protection member 113. In FIG. 3, the cover window CW, which includes the window 111, the opaque layer 112, the window protection member 113, and a hard coating layer 117, is disposed on the display panel 100 and the polarizing film 110.

Referring to FIG. 3, in an embodiment, the cover window CW includes the window 111, the opaque layer 112, the window protection member 113, and the hard coating layer 117. In an embodiment, the window 111 includes ultra-thin glass (UTG™). However, embodiments of the disclosure are not necessarily limited thereto. In an embodiment, the window 111 includes a polymer resin.

The window protection member 113 is disposed on the window 111. The window protection member 113 is adhered to a top surface of the window 111 through the second adhesive layer 122. The window protection member 113 protects the window 111 from external impacts, and prevents or minimizes scratches on the top surface of the window 111. In an embodiment, the window protection member 113 includes a polymer resin. However, embodiments of the disclosure are not necessarily limited thereto. In an embodiment, the window protection member 113 includes an inorganic material.

In an embodiment, the opaque layer 112 is disposed between the window protection member 113 and the second adhesive layer 122. However, embodiments of the disclosure are not necessarily limited thereto. In an embodiment, the opaque layer 112 is disposed on a portion of the window protection member 113. The opaque layer 112 is formed of an opaque material so that a wiring or a circuit of the display apparatus 1 is not externally visible.

The hard coating layer 117 is disposed on the window protection member 113. In an embodiment, the hard coating layer 117 includes an organic material such as a polymer resin. However, embodiments of the disclosure are not necessarily limited thereto. In an embodiment, the hard coating layer 117 includes an inorganic material.

The hard coating layer 117 is an outermost layer of the cover window CW. For example, the outermost layer of the cover window CW is an outermost layer of the display apparatus 1. The outermost layer of the cover window CW can be directly touched by a user, and when the outermost layer of the cover window CW is UTG™ or the window protection member 113, a user's touch may be degraded. However, because the hard coating layer 117 is provided as the outermost layer of the cover window CW, a smooth and soft touch feeling can be provided to the user.

In an embodiment, the planarization film 105 is disposed under the display panel 100. The planarization film 105 is disposed on the first support member 140 and compensates for unevenness of the first support member 140, and planarizes a surface, such as a top surface of the planarization film 105, on which the display panel 100 is to be disposed. Because of the planarization film 105, when the display apparatus 1 is viewed from above, such as from a z direction, a surface of the display apparatus 1 appears flat. The display panel 100, etc., is securely disposed on the top surface of the planarization film 105. However, embodiments of the disclosure are not necessarily limited thereto. In an embodiment, the planarization film 105 is omitted.

The planarization film 105 includes at least one of a plastic or a metal. When the planarization film 105 includes plastic, the planarization film 105 includes at least one of thermoplastic polyurethane (TPU), polyimide (PI), or polyethylene terephthalate (PET). In addition, when the planarization film 105 includes metal, the planarization film 105 includes one of stainless use steel (SUS), or a compound of magnesium (Mg), aluminum (Al), or titanium (TI). However, embodiments of the disclosure are not necessarily limited thereto.

In an embodiment, the first support member 140 is disposed under the planarization film 105. The first support member 140 includes a first portion 140a, a second portion 140b, and a foldable structure 145. The first portion 140a at least partially overlaps the first display area DA1, and the second portion 140b at least partially overlaps the second display area DA2. The first portion 140a and the second portion 140b are spaced apart from each other in the y direction. The foldable structure 145 is provided between the first portion 140a and the second portion 140b.

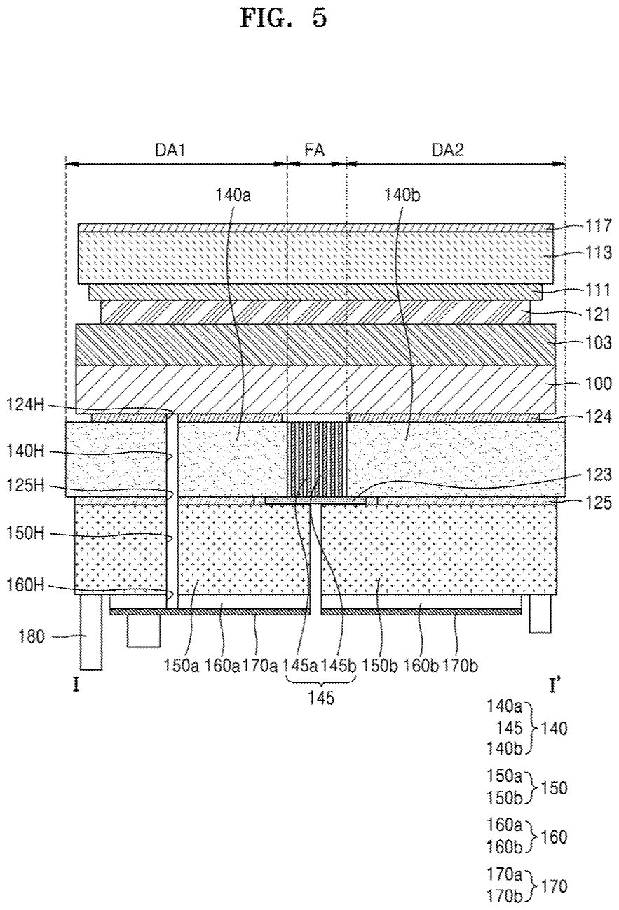

The first support member 140 is disposed under the display panel 100 and supports the display panel 100. In addition, the first support member 140 is disposed on a digitizer 150 (see FIG. 5) described below to protect the digitizer 150 from external impacts.

In an embodiment, the first support member 140 includes the foldable structure 145. When the display apparatus 1 is folded, a shape or a length of the foldable structure 145 can vary. In an embodiment, the foldable structure 145 in the first support member 140 includes uneven members or links that are rotatably connected to each other. However, embodiments of the disclosure are not necessarily limited thereto.

The foldable structure 145 includes portions 145a in which a metal is disposed and an opening 145b between the portions 145a. The first portion 140a and the second portion 140b are disposed on both sides of the folding axis FAX. Because the foldable structure 145 includes the portions 145a in which a metal is disposed and the opening 145b between the portions 145a disposed, the first support member 140 can be more easily folded.

When the display apparatus 1 is folded, the foldable structure 145 is folded around the folding axis FAX. In the foldable structure 145, the first portion 140a and the second portion 140b are symmetrical to each other. A portion of the first support member 140 other than the foldable structure 145 has a flat top surface.

In an embodiment, the first support member 140 includes at least one of glass, plastic, or metal. The first support member 140 includes at least one of stainless use steel (SUS), carbon fiber reinforced plastic (CFRP), or glass fiber reinforced plastic (GFRP). In addition, the first support member 140 may include Al, Ti, Mg, or a compound thereof. Alternatively, the first support member 140 includes one of an Al alloy, a Ti alloy, or an Mg alloy. The foldable structure 145 and the first portion 140a and the second portion 140b may include the same material or different materials.

A third adhesive layer 123 is disposed over or under the foldable structure 145 of the first support member 140. The third adhesive layer 123 includes a first-third adhesive layer 123a disposed over the folding structure 145 and a second-third adhesive layer 123b disposed under the folding structure 145, as shown in FIG. 2. The third adhesive layer 123 prevents or minimizes penetration of foreign materials into the foldable structure 145 of the first support member 140. In an embodiment, the third adhesive layer 123 includes thermoplastic polyurethane (TPU). However, embodiments of the disclosure are not necessarily limited thereto.

In an embodiment, the heat dissipating layer 160 is disposed under the first support member 140. The heat dissipating layer 160 includes a first heat dissipating layer 160a and a second heat dissipating layer 160b. The first heat dissipating layer 160a at least partially overlaps the first display area DA1 and/or the first portion 140a of the first support member 140. The second heat dissipating layer 160b at least partially overlaps the second display area DA2 and/or the second portion 140b of the first support member 140. The first heat dissipating layer 160a and the second heat dissipating layer 160b are spaced apart from each other in the y direction.

The heat dissipating layer 160 dissipates heat generated in the battery 170 disposed under the heat dissipating layer 160. In addition, the heat dissipating layer 160 dissipates heat generated in the digitizer 150 (see FIG. 5) disposed under the heat dissipating layer 160. The heat dissipating layer 160 includes copper (Cu) or graphite. For example, the heat dissipating layer 160 is one of a Cu film, a tape that uses Cu particles as a filler, a graphite film, or a graphite tape. However, embodiments of the disclosure are not necessarily limited thereto.

In an embodiment, the battery 170 is disposed under the heat dissipating layer 160. The battery 170 includes a first battery 170a and a second battery 170b. The first battery 170a at least partially overlaps the first display area DA1 and/or the first portion 140a of the first support member 140 and/or the first heat dissipating layer 160a. The second battery 170b at least partially overlaps the second display area DA2 and/or the second portion 140b of the first support member 140 and/or the second heat dissipating layer 160b. The first battery 170a and the second battery 170b are spaced apart from each other in the y direction. The first battery 170a and the second battery 170b are disposed in a lower structure of the display apparatus 1 and are integrally provided with the lower structure.

When the battery 170 is separately provided in the display apparatus 1, a volume of the battery 170 is about twice a volume of a display module of the display apparatus 1, and imposes limitations in the design of a lower structure of the foldable display apparatus 1. When the battery 170 is integrally formed by being embedded in the lower structure of the display apparatus 1, the lower structure of the display apparatus 1 can be more easily designed.

In addition, because the foldable display apparatus 1 typically needs various functions such as heat dissipation, electromagnetic wave shielding, impact reduction, or a digitizer for pen recognition, an auxiliary power supply may be additionally required. The battery 170 integrally provided in the display module of the display apparatus 1 functions as an auxiliary power supply by supplying power in an emergency situation. For example, when a main battery of the display apparatus 1 runs out, the display apparatus 1 can be used by using the battery 170 in an emergency situation. For example, the battery 170 operates when a remaining capacity of the main battery is 15% or less. To this end, a sensor and a driver integrated circuit (IC) that recognize a battery capacity, check a set battery capacity and cause an auxiliary battery of the disclosure to apply a voltage may be additionally provided on a main body of the display apparatus 1.

In an embodiment, the battery 170 is flexible. When the battery 170 is flexible, the battery 170 includes a physically crosslinked organogel that is an active material or a separator of a positive electrode and a negative electrode. When a material of the battery 170 includes a physically crosslinked organogel, an adhesive force of the battery 170 is increased by emitting an electron beam (E-beam) to the organogel. The E-beam is emitted to the flexible battery 170 to increase an adhesive force, and a set, such as the lower structure of the display apparatus 1, is attached by using the flexible battery 170 as an adhesive. For example, a separate adhesive layer is not required. However, embodiments of the disclosure are not necessarily limited thereto.

In an embodiment, the battery 170 is formed by using a printing method. When the battery 170 formed by using a printing method is used as the battery 170 embedded in the lower structure of the display apparatus 1, the battery 170 can be directly manufactured on the support member of the foldable display apparatus 1. In addition, a battery-integrated support member can be subsequently formed as one layer.

In an embodiment, through-holes 121H, 110H, 100H, 105H, 140H, and 160H that correspond to the second display area DA2 are respectively formed in the first adhesive layer 121, the polarizing film 110, the display panel 100, the planarization film 105, the first support member 140, and the heat dissipating layer 160. However, embodiments of the disclosure are not necessarily limited thereto. In an embodiment, no through-hole is formed in at least one of the first adhesive layer 121, the polarizing film 110, the display panel 100, the planarization film 105, the first support member 140, or the heat dissipating layer 160. Because the through-holes 121H, 110H, 100H, 105H, 140H, and 160H are formed in the first adhesive layer 121, the polarizing film 110, the display panel 100, the planarization film 105, the first support member 140, and the heat dissipating layer 160, a light transmittance of the second display area DA2 increases, thereby providing the display apparatus 1 that includes an electronic module with increased performance.

In an embodiment, although the through-holes 121H, 110H, 100H, 105H, 140H, and 160H correspond to the second display area DA2 of the display apparatus 1, as illustrated in FIG. 2, embodiments of the disclosure are not necessarily limited thereto. In an embodiment, the through-holes 121H, 110H, 100H, 105H, 140H, and 160H are formed that correspond to the first display area DA1 of the display apparatus 1.

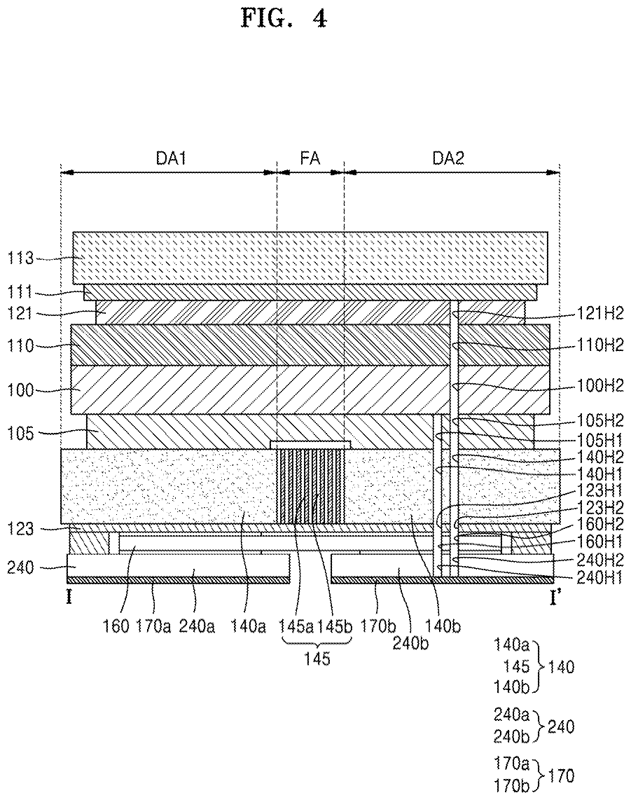

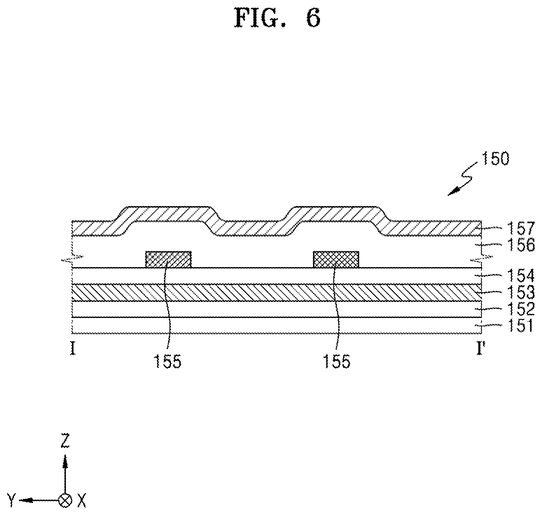

FIGS. 4 and 5 are cross-sectional views of the display apparatus 1, according to embodiments. For example, FIGS. 4 and 5 are cross-sectional views taken along the line I-I′ of the display apparatus 1 of FIG. 2. FIG. 6 is a cross-sectional view of the digitizer 150 of FIG. 5.

Referring to FIG. 4, in the display apparatus 1 according to an embodiment, a second support member 240 is further disposed between the first support member 140 and the battery 170. An upper structure that includes the first support member 140 of the display apparatus 1 according to an embodiment is the same as or similar to that of the display apparatus 1 of FIG. 1. The upper structure that includes the first support member 140 has been described with reference to FIGS. 2 and 3, and thus, a repeated description will be omitted. Although the adhesive layer 121 is disposed between the polarizing film 110 and the window 111 in FIG. 4, embodiments of the disclosure are not necessarily limited thereto.

In an embodiment, the third adhesive layer 123 is entirely disposed under the first support member 140. The third adhesive layer 123 prevents or minimizes penetration of foreign materials into the foldable structure 145 of the first support member 140.

In an embodiment, the heat dissipating layer 160 is entirely disposed under the third adhesive layer 123. The heat dissipating layer 160 dissipates heat generated in in the battery 170 or heat generated in the digitizer 150 disposed under the heat dissipating layer 160. The heat dissipating layer 160 includes Cu or graphite. However, embodiments of the disclosure are not necessarily limited thereto.

In an embodiment, the second support member 240 is disposed under the heat dissipating layer 160. The second support member 240 includes a third portion 240a and a fourth portion 240b. The third portion 240a at least partially overlaps the first display area DA1 and/or the first portion 140a of the first support member 140. The fourth portion 240b at least partially overlaps the second display area DA2 and/or the second portion 140b of the first support member 140. The third portion 240a and the fourth portion 240b of the second support member 240 are spaced apart from each other in the y direction.

In an embodiment, the second support member 240 includes at least one of glass, plastic, or a metal, like the first support member 140. The second support member 140 may include SUS, CFRP, or GFRP. In an embodiment, the second support member 140 includes one of Al, Ti, Mg, or a compound thereof. In an embodiment, the second support member 140 includes one of an Al alloy, a Ti alloy, or an Mg alloy. However, embodiments of the disclosure are not necessarily limited thereto. In an embodiment, the second support member 240 and the first support member 140 include different materials.

In an embodiment, the battery 170 is disposed under the second support member 240. The battery 170 includes the first battery 170a and the second battery 170b. For example, the first battery 170a is disposed under the third portion 240a of the second support member 240, and the second battery 170b is disposed under the fourth portion 240b of the second support member 240. The first battery 170a at least partially overlaps the first display area DA1 and/or the first portion 140a of the first support member 140. The second battery 170b at least partially overlaps the second display area DA2 and/or the second portion 140b of the first support member 140. The first battery 170a and the second battery 170b are spaced apart from each other in the y direction. The first battery 170a and the second battery 170b are disposed in a display module and are integrally provided. Because the battery 170 is integrally provided in the display module, design limitations caused by a volume of an existing battery in a lower structure of the display apparatus 1 can be overcome. In addition, the battery 170 embedded in the display module can function as an auxiliary power supply so that the display apparatus 1 can be used in an emergency situation. The battery 170 may be a flexible battery 170 or a printable battery 170.

In an embodiment, two holes that pass through each layer are formed in the second display area DA2 of the display apparatus 1. First through-holes 105H1, 140H1, 123H1, 160H1, and 240H1 that correspond to the second display area DA2 are formed in the planarization film 105, the first support member 140, the third adhesive layer 123, the heat dissipating layer 160, and the second support member 240. In addition, second through-holes are formed on the right of the first through-holes 105H1, 140H1, 123H1, 160H1, and 240H1. Second through-holes 121H2, 110H2, 100H2, 105H2, 140H2, 123H2, 160H2, and 240H2 that correspond to the second display area DA2 are formed in the first adhesive layer 121, the polarizing film 110, the display panel 100, the planarization film 105, the first support member 140, the third adhesive layer 123, the heat dissipating layer 160, and the second support member 240.

Although the first through-holes 105H1, 140H1, 123H1, 160H1, and 240H1 and the second through-holes 121H2, 110H2, 100H2, 105H2, 140H2, 123H2, 160H2, and 240H2 are illustrated in FIG. 4 corresponding to the second display area DA2 of the display apparatus 1, embodiments of the disclosure are not necessarily limited thereto. In an embodiment, the first through-holes 105H1, 140H1, 123H1, 160H1, and 240H1 and the second through-holes 121H2, 110H2, 100H2, 105H2, 140H2, 123H2, 160H2, and 240H2 are formed that correspond to the first display area DA1 of the display apparatus 1.

Because of the first through-holes 105H1, 140H1, 123H1, 160H1, and 240H1 and the second through-holes 121H2, 110H2, 100H2, 105H2, 140H2, 123H2, 160H2, and 240H2 that correspond to the second display area DA2 of the display apparatus 1, a light transmittance may increase, thereby providing the display apparatus 1 that includes an electronic module with increased performance.

A cross-sectional view of the display apparatus 1 of FIG. 5 and a cross-sectional view of the display apparatus 1 of FIG. 2 are similar to each other in some structures, but are different from each other in that the digitizer 150 is additionally disposed between the first support member 140 and the battery 170, a an impact absorbing layer 103 replaces the polarizing film 110 between the display panel 100 and the first adhesive layer 121, a fourth adhesive layer 124 is disposed between the display panel 100 and the first support member 140, and a fifth adhesive layer 125 is disposed between the first support member 140 and the digitizer 150. However, embodiments of the disclosure are not necessarily limited thereto. In an embodiment, the first, fourth, and fifth adhesive layers 121, 124, and 125 are PSAs. However, embodiments of the disclosure are not necessarily limited thereto.

Referring to FIG. 5, in an embodiment, the impact absorbing layer 103 is disposed on the display panel 100. The impact absorbing layer 103 is disposed in an upper portion of the display apparatus 1 and protects the display panel 100 from external impacts. The impact absorbing layer 103 includes a polymer resin. The polymer resin may be one or more of polyethersulfone, polyacrylate, polyether imide, polyethylene naphthalate, polyethylene terephthalate, polyphenylene sulfide, polyarylate, polyimide, polycarbonate, or cellulose acetate propionate. However, embodiments of the disclosure are not necessarily limited thereto. In an embodiment, the impact absorbing layer 103 includes a material such as glass or quartz.

In an embodiment, the window 111 is disposed on the impact absorbing layer 103. In an embodiment, the window 111 includes UTG™. However, embodiments of the disclosure are not necessarily limited thereto. The window 111 is adhered to a top surface of the impact absorbing layer 103 through the first adhesive layer 121.

In an embodiment, the window protection member 113 is disposed on the window 111.

The window protection member 113 protects the window 111 from external impacts, and prevents or minimizes scratches on a top surface of the window 111. The hard coating layer 117 (see FIG. 3) is disposed on the window protection member 113. The hard coating layer 117 provides a smooth and soft touch feel to a user.

In an embodiment, the first support member 140 is disposed under the display panel 100. The first support member 140 is attached onto a bottom surface of the display panel 100 by the fourth adhesive layer 124. The first support member 140 includes the first portion 140a, the second portion 140b, and the foldable structure 145. The first portion 140a of the first support member 140 overlaps at least a part of the first display area DA1. The second portion 140b of the first support member 140 overlaps at least a part of the second display area DA2. The foldable structure 145 is disposed between the first portion 140a and the second portion 140b. The foldable structure 145 includes the portions 145a in which a metal is disposed, and the opening 145b between the portions 145a. Because the foldable structure 145 is part of the first support member 140, the first support member 140 can be more easily folded.

In an embodiment, the third adhesive layer 123 is disposed under the foldable structure 145. The third adhesive layer 123 includes TPU. The third adhesive layer 123 prevents or minimizes penetration of foreign materials into the foldable structure 145. However, embodiments of the disclosure are not necessarily limited thereto.

In an embodiment, the digitizer 150 is disposed under the first support member 140. The digitizer 150 is attached onto a bottom surface of the first support member 140 by the fifth adhesive layer 125. The digitizer 150 includes a first digitizer 150a and a second digitizer 150b. The first digitizer 150a at least partially overlaps the first display area DA1. The second digitizer 150b at least partially overlaps the second display area DA2. The first digitizer 150a and the second digitizer 150b are spaced apart from each other in the y direction.

FIG. 6 illustrates a detailed structure of the digitizer 150. Referring to FIG. 6, in an embodiment, the digitizer 150 includes a first layer 151, an eighth adhesive layer 152, a first pattern layer 153, a second layer 154, a ninth adhesive layer 156, a second pattern layer 155, and a third layer 157. In an embodiment, the first pattern layer 153 and the second pattern layer 155 are disposed on different surfaces of the second layer 154. In an embodiment, the first pattern layer 153 and the second pattern layer 155 are stacked on each other. For example, the first pattern layer 153 and the second pattern layer 155 are disposed on different layers. For convenience of explanation, the following will be described assuming that the first pattern layer 153 and the second pattern layer 155 of the digitizer 150 are disposed on different surfaces of the second layer 154.

The first pattern layer 153 is disposed on a bottom surface of the second layer 154, and the second pattern layer 155 is disposed on a top surface of the second layer 154. For example, the first pattern layer 153 directly contacts the bottom surface of the second layer 154, and the second pattern layer 155 directly contacts the top surface of the second layer 154. The first pattern layer 153 and the second pattern layer 155 are formed by stacking a pattern layer on each of the bottom surface and the top surface of the second layer 154 and leaving a part of the pattern layer and removing another part of the pattern layer.

The first pattern layer 153 and the second pattern layer 155 have a loop coil shape. The first pattern layer 153 and the second pattern layer 155 can identify a location of an electronic pen by generating an induced current when the electronic pen contacts or hovers over the display apparatus 1. For example, the first pattern layer 153 and the second pattern layer 155 are arranged in different directions. For example, when the second pattern layer 155 is arranged in one of the first direction (x direction) and the second direction (y direction), the first pattern layer 153 is arranged in the other of the first direction (x direction) and the second direction (y direction). For example, when the second pattern layer 155 is arranged in the first direction (x direction), the first pattern layer 153 is arranged in the second direction (y direction), and when the second pattern layer 155 is arranged in the second direction (y direction), the first pattern layer 153 is arranged in the first direction (x direction). In this case, the first pattern layer 153 and the second pattern layer 155 intersect each other.

The first layer 151 is disposed under the first pattern layer 153, and the third layer 157 is disposed over the second pattern layer 155. The first layer 151 and the third layer 157 respectively shield the first pattern layer 153 and the second pattern layer 155 to prevent the first pattern layer 153 and the second pattern layer 155 from being oxidized due to exposure to external moisture or oxygen.

In an embodiment, each of the first layer 151 and the third layer 157 includes a polyimide resin. In an embodiment, each of the first layer 151 and the third layer 157 includes at least one light absorbing material selected from a polyimide resin, a black dye, a black pigment, or a black filler.

The eighth adhesive layer 152 is disposed between the first layer 151 and the first pattern layer 153. In an embodiment, the eighth adhesive layer 152 is integrally formed with the first layer 151. For example, the eighth adhesive layer 152 is a PSA.

The ninth adhesive layer 156 is disposed between the third layer 157 and the second pattern layer 155. In an embodiment, the ninth adhesive layer 156 is integrally formed with the third layer 157. For example, the ninth adhesive layer 156 is a PSA.

In an embodiment, the first layer 151 and the third layer 157 are formed from the same or similar materials. For example, the second layer 154 includes a polyimide resin.

Referring back to FIG. 5, an electromagnetic wave absorbing layer is disposed under the digitizer 150. The electromagnetic wave absorbing layer includes a first electromagnetic wave absorbing layer and a second electromagnetic wave absorbing layer. The first electromagnetic wave absorbing layer is disposed under the first digitizer 150a. The second electromagnetic wave absorbing layer is disposed under the second digitizer 150b. For example, the first electromagnetic wave absorbing layer at least partially overlaps the first display area DA1. The second electromagnetic wave absorbing layer at least partially overlaps the second display area DA2. The first electromagnetic wave absorbing layer and the second electromagnetic wave absorbing layer are spaced apart from each other in the y direction.

The electromagnetic wave absorbing layer includes a magnetic metal powder (MMP). Because the electromagnetic wave absorbing layer includes an MMP, electromagnetic waves incident on the digitizer 150 or electromagnetic waves emitted from the digitizer 150 are absorbed. Because the electromagnetic wave absorbing layer is disposed under the digitizer 150, noise generated due to other electromagnetic waves is reduced.

In an embodiment, the heat dissipating layer 160 is disposed under the digitizer 150. The heat dissipating layer 160 includes the first heat dissipating layer 160a and the second heat dissipating layer 160b. The first heat dissipating layer 160a is disposed under the first digitizer 150a, and overlaps at least a part of the first display area DA1. The second heat dissipating layer 160b is disposed under the second digitizer 150b, and overlaps at least a part of the second display area DA2. The heat dissipating layer 160 includes one of Cu or graphite. The heat dissipating layer 160 dissipates heat generated in the battery 170 disposed under the heat dissipating layer 160.

In an embodiment, the battery 170 is disposed under the heat dissipating layer 160. The battery 170 includes the first battery 170a and the second battery 170b. The first battery 170a is disposed under the first heat dissipating layer 160a, and at least partially overlaps the first portion 140a of the first support member 140. The second battery 170b is disposed under the second heat dissipating layer 160b, and at least partially overlaps the second portion 140b of the first support member 140.

In an embodiment, a waterproof member 180 is disposed under the digitizer 150 and the heat dissipating layer 160. The waterproof member 180 blocks or absorbs externally introduced moisture and prevents or minimizes damage to elements of the display apparatus 1 due to the moisture. The waterproof member 180 is one of a tape or a sponge.

In an embodiment, through-holes 124H, 140H, 125H, 150H, and 160H that correspond to the first display area DA1 are formed in the fourth adhesive layer 124, the first support member 140, the fifth adhesive layer 125, the digitizer 150, and the heat dissipating layer 160. However, embodiments of the disclosure are not necessarily limited thereto. In an embodiment, no through-hole is formed in at least one of the fourth adhesive layer 124, the first support member 140, the fifth adhesive layer 125, the digitizer 150, and the heat dissipating layer 160.

In addition, although FIG. 5 shows that the through-holes 124H, 140H, 125H, 150H, and 160H correspond to the first display area DA1, embodiments of the disclosure are not necessarily limited thereto. In an embodiment, the through-holes 124H, 140H, 125H, 150H, and 160H that correspond to the second display area DA2 are formed.

Because of the through-holes 124H, 140H, 125H, 150H, and 160H that correspond to the first display area DA1, a light transmittance of the first display area DA1 increases, thereby providing the display apparatus 1 that includes an electronic module with increased performance.

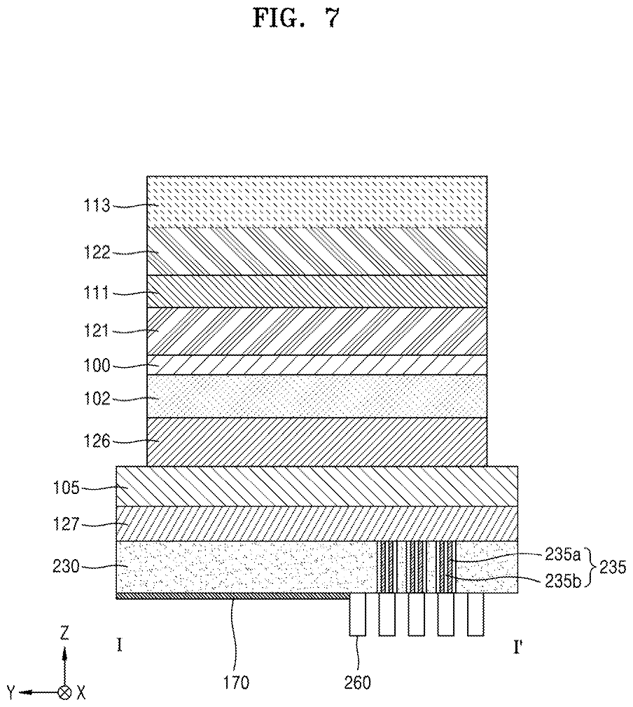

FIG. 7 is a cross-sectional view of the display apparatus 1, according to an embodiment. FIG. 7 illustrates a rollable display apparatus 1, which differs from a foldable display apparatus 1 described above. The display apparatus 1 differs from the foldable display apparatus 1 described above in that a structure is disposed under the display panel 100.

Referring to FIG. 7, the window 111 is disposed on the display panel 100. In an embodiment, the window 111 includes UTG™. However, embodiments of the disclosure are not necessarily limited thereto. The window protection member 113 is disposed on the window 111. The window protection member 113 is attached onto the window 111 by the second adhesive layer 122.

In an embodiment, a protective film 102 is disposed under the display panel 100. The planarization film 105 is disposed under the protective film 102. The planarization film 105 is attached onto the protective film 102 by a sixth adhesive layer 126. The planarization film 105 compensates for unevenness of a support member 230 disposed under the planarization film 105, so that the display apparatus 1 has a flat surface when viewed from above, such as from the z direction. However, embodiments of the disclosure are not necessarily limited thereto. In an embodiment, the planarization film 105 is omitted.

In an embodiment, the support member 230 is disposed under the planarization film 105. The support member 230 is attached onto the planarization film 105 by a seventh adhesive layer 127. The support member 230 includes a foldable structure 235 in a right portion, such as in a −y direction. The folding structure 235 include portions 235a that include a metal and an opening 235b formed between the portions 235a. In the foldable structure 235, the portions 235a and the openings 235b are not arranged at a regular interval. For example, the foldable structures 235 are spaced apart from each other in a right portion of the support member 230, such as in the −y direction. However, embodiments of the disclosure are not necessarily limited thereto.

The battery 170 is disposed under a left portion of the support member 230 in the y-direction.

In an embodiment, a multi-bar 260 is disposed under the support member 230. In the rollable display apparatus 1, the multi-bar 260 fixes a shape of the display apparatus 1 when the display apparatus 1 is unrolled.

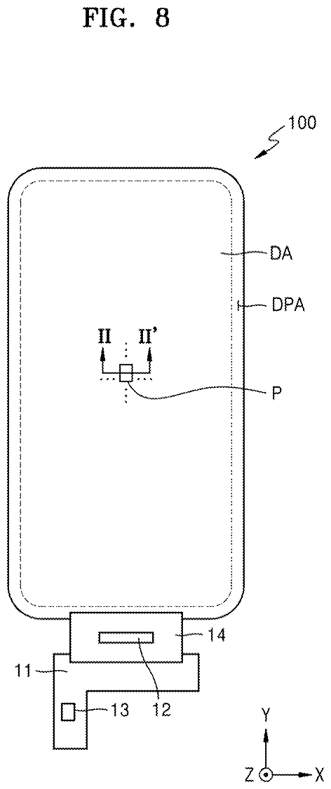

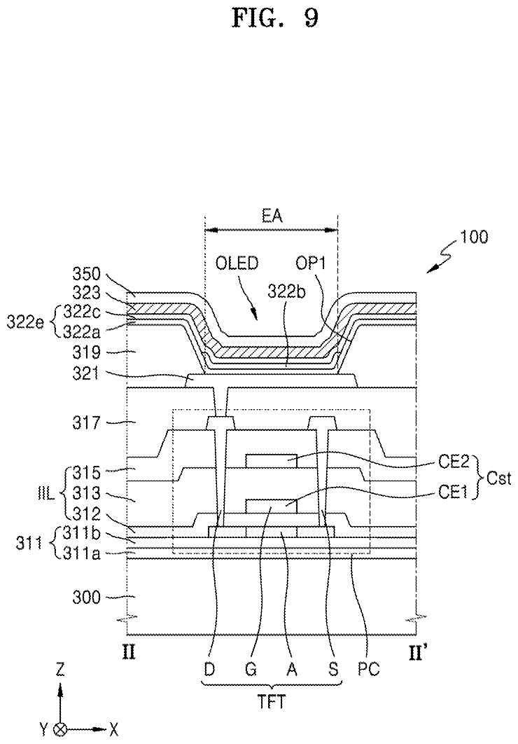

FIG. 8 is a plan view of the display panel 100 of the display apparatus 1, according to an embodiment. FIG. 9 is a cross-sectional view taken along a line II-II′ of FIG. 8.

Referring to FIGS. 8 and 9, in an embodiment, the display panel 100 includes the display area DA and the peripheral area DPA outside the display area DA. The display panel 100 provides an image by using pixels P disposed in the display area DA.

The pixels P are display elements such as organic light-emitting diodes OLED. Each pixel P emits, for example, one of red light, green light, blue light, or white light. The display area DA may be covered with an encapsulation member for protection from external air or moisture.

A first flexible film 14 is attached to an edge of a side of the display panel 100. A first side of the first flexible film 14 is attached to the edge of the side of the display panel 100 by using an anisotropic conductive film. The first flexible film 14 can be bent.

A display driver 12 is disposed on the first flexible film 14. The display driver 12 receives control signals and power supply voltages, and generates and outputs signals and voltages that drive the display panel 100. The display driver 12 may be formed as an integrated circuit (IC).

A display circuit board 11 is attached to a second side of the first flexible film 14 that is opposite to the first side. The second side of the first flexible film 14 is attached to a top surface of the display circuit board 11 by using an anisotropic conductive film. The display circuit board 11 is one of a flexible printed circuit board (FPCB) that can be bent, a rigid printed circuit board (PCB) that is not easily bent, or a hybrid printed circuit board that includes both a rigid printed circuit board and a flexible printed circuit board.

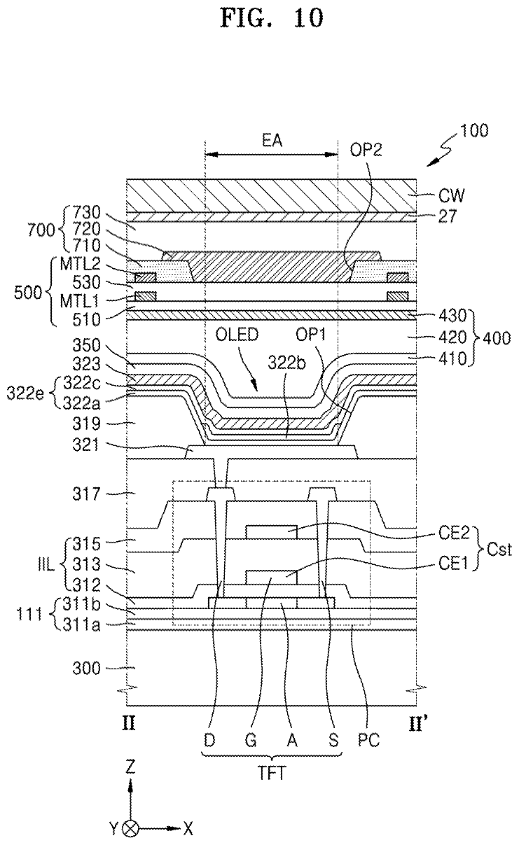

A touch sensor driver 13 is disposed on the display circuit board 11. The touch sensor driver 13 may be formed as an integrated circuit. The touch sensor driver 13 is attached to the display circuit board 11. The touch sensor driver 13 is electrically connected to touch electrodes of a touch screen layer 500 (see FIG. 10) of the display panel 100 through the display circuit board 11.

The touch screen layer 500 (see FIG. 10) of the display panel 100 detects a touch input of a user by using at least one of various touch methods, such as a resistive method or a capacitive method. For example, when the touch screen layer 500 of the display panel 100 detects a touch input of a user by using a capacitive method, the touch sensor driver 13 transmits driving signals to driving electrodes of the touch electrodes, and determines whether the user touches by detecting voltages charged in mutual capacitances between the driving electrodes and sensing electrodes of the touch electrodes. The user's touch may be a contact touch or a proximity touch. A contact touch refers to an object, such as the user's finger or a pen, directly contacting the cover window CW disposed on the touch screen layer. A proximity touch refers to an object, such as the user's finger or a pen, being disposed close to the cover window CW, such as hovering. The touch sensor driver 13 transmits sensor data to a main processor according to the detected voltages, and the main processor calculates touch coordinates where the touch input occurs by analyzing the sensor data.

In addition, a power supply unit that supplies driving voltages that drive the pixels P, a scan driver, and the display driver 12 of the display panel 100 may be additionally disposed on the display circuit board 11. Alternatively, the power supply unit may be integrated with the display driver 12, and the display driver 12 and the power supply unit may be implemented as one integrated circuit.

Referring now to FIG. 9, in an embodiment, substrate 300 is formed of an insulating material, such as glass, quartz, or a polymer resin. For example, the substrate 130 includes a polymer resin such as one or more of polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 300 may have a multi-layer structure that includes a layer that includes the polymer resin and an inorganic layer. For example, the substrate 300 includes two layers that include the polymer resin, and an inorganic barrier layer disposed between the two layers. The substrate 300 may be a rigid substrate, or a flexible substrate that is bendable, foldable, or rollable.

A buffer layer 311 is disposed on the substrate 300, and reduces or prevents penetration of foreign materials, moisture, or external air from the bottom of the substrate 300 and planarizes the substrate 300. The buffer layer 311 may include an inorganic material such as an oxide or a nitride, an organic material, or a combination of an organic material and an inorganic material, and may have a single or multi-layer structure that includes an inorganic material and an organic material. A barrier layer may be further disposed between the substrate 300 and the buffer layer 311 to prevent penetration of external air. In an embodiment, the buffer layer 311 includes silicon oxide (SiO₂) or silicon nitride (SiNₓ). The buffer layer 311 includes a first buffer layer 311a and a second buffer layer 311b that are stacked. In an embodiment, the first buffer layer 311a includes silicon oxide (SiO₂), and the second buffer layer 311b includes silicon nitride (SiNₓ). In an embodiment, the first buffer layer 311a includes silicon nitride (SiNₓ), and the second buffer layer 311b includes silicon nitride (SiO₂) In an embodiment, the first buffer layer 311a and the second buffer layer 311b include the same material.

A pixel circuit PC is disposed on the buffer layer 311. The pixel circuit PC includes a thin-film transistor TFT and a storage capacitor Cst. The thin-film transistor TFT is disposed on the buffer layer 311. The thin-film transistor TFT includes a semiconductor layer A, a gate electrode G, a source electrode S, and a drain electrode D. The thin-film transistor TFT is connected to an organic light-emitting diode OLED and drives the organic light-emitting diode OLED.

The semiconductor layer A is disposed on the buffer layer 311, and includes polysilicon. In an embodiment, the semiconductor layer A includes amorphous silicon. In an embodiment, the semiconductor layer A includes an oxide of at least one of indium (In), gallium (Ga), stannum (Sn), zirconium (Zr), vanadium (V), hafnium (Hf), cadmium (Cd), germanium (Ge), chromium (Cr), titanium (Ti), or zinc (Zn). The semiconductor layer A includes a channel region, and a source region and a drain region doped with impurities.

A first insulating layer 312 that covers the semiconductor layer A is disposed the buffer layer 311. The first insulating layer 312 includes an inorganic insulating material, such as one or more of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂) The first insulating layer 312 may have a single or multi-layer structure that includes the above inorganic insulating materials.

The gate electrode G is disposed on the first insulating layer 312 and overlaps the semiconductor layer A. The gate electrode G includes one or more of molybdenum (Mo), aluminum (Al), copper (Cu), or titanium (Ti), and may have a single or multi-layer structure. In an embodiment, the gate electrode G has a single layer structure that includes molybdenum (Mo).

A second insulating layer 313 that covers the gate electrode G is disposed on the first insulating layer 312. The second insulating layer 313 includes an inorganic insulating material such as one or more of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂) The second insulating layer 313 may have a single or multi-layer structure that includes the above inorganic insulating materials.

An upper electrode CE2 of the storage capacitor Cst is disposed on the second insulating layer 313. The upper electrode CE2 overlaps the gate electrode G disposed under the upper electrode CE2. The gate electrode G and the upper electrode CE2 that overlap each other with the second insulating layer 313 therebetween constitute the storage capacitor Cst. In an embodiment, the gate electrode G is a lower electrode CE1 of the storage capacitor Cst. In an embodiment, the lower electrode CE1 of the storage capacitor Cst is a separate independent element. For example, the lower electrode CE1 and the gate electrode G are spaced apart from each other by a predetermined interval.

The upper electrode CE2 includes one or more of aluminum (Al), platinum (Pt), palladium (Pd), silver (Ag), magnesium (Mg), gold (Au), nickel (Ni), neodymium (Nd), iridium (Jr), chromium (Cr), calcium (Ca), molybdenum (Mo), titanium (Ti), tungsten (W), or copper (Cu), and may have a single or multi-layer structure that includes the above materials.

A third insulating layer 315 that covers the upper electrode CE2 is disposed on the second insulating layer 313. The third insulating layer 315 includes an inorganic insulating material such as one or more of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂) The third insulating layer 315 may have a single or multi-layer structure that includes the inorganic insulating material.

The source electrode S and the drain electrode D are disposed on the third insulating layer 315. Each of the source electrode S and the drain electrode D includes a conductive material that includes at least one of molybdenum (Mo), aluminum (Al), copper (Cu), or titanium (Ti), and may have a single or multi-layer structure that includes the above materials. In an embodiment, each of the source electrode S and the drain electrode D has a multi-layer structure of titanium (Ti)/aluminum (Al)/titanium (Ti).

A planarization layer 317 is disposed on the source electrode S, the drain electrode D and the third insulating layer 315. The planarization layer 317 has a flat top surface so that a pixel electrode 321 disposed on the planarization layer 317 is flat.

The planarization layer 317 may include an organic material or an inorganic material, and may have a single or multi-layer structure. For example, planarization layer 317 includes at least one of benzocyclobutene (BCB), polyimide, hexamethyldisiloxane (HMDSO), a general-purpose polymer such as polymethyl methacrylate (PMMA) or polystyrene (PS), a polymer derivative with a phenol-based group, an acrylic polymer, an imide-based polymer, an aryl ether-based polymer, an amide-based polymer, a fluorinated polymer, a p-xylene-based polymer, or a vinyl alcohol-based polymer. The planarization layer 317 also includes an inorganic insulating material such as at least one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂) Forming the planarization layer 317 includes forming a layer and then chemical mechanical polishing a top surface of the layer to provide a flat top surface.

The planarization layer 317 includes a via hole through which one of the source electrode S or the drain electrode D of the thin-film transistor TFT is exposed, and the pixel electrode 321 contacts one of the source electrode S or the drain electrode D through the via hole and electrically connects to the thin-film transistor TFT.

Although one planarization layer 317 is illustrated in FIG. 8, in an embodiment, two planarization layers 317 are provided. When two planarization layers 317 are provided, high integration can be more easily achieved.

The pixel electrode 321 is disposed on the planarization layer 317. The pixel electrode 321 includes a conductive oxide such as one of indium tin oxide (ITO), indium zinc oxide (IZO), zinc oxide (ZnO), indium oxide (In₂O₃), indium gallium oxide (IGO), or aluminum zinc oxide (AZO). The pixel electrode 321 also includes a reflective layer that includes one or more of silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 321 has a structure in which films formed of ITO, IZO, ZnO, or In₂O₃ are disposed over or under the reflective film. For example, the pixel electrode 321 has a structure in which indium tin oxide (ITO)/silver (Ag)/indium tin oxide (ITO) are stacked.

A pixel-defining film 319 is disposed on the planarization layer 317. The pixel-defining film 319 covers an edge of the pixel electrode 321. A first opening OP1 through which at least a part of the pixel electrode 321 is exposed is formed in the pixel-defining film 319. A size and a shape of an emission area EA of the organic light-emitting diode OLED, that is, the pixel P, is defined by the first opening OP1.

The pixel-defining film 319 increases a distance between the edge of the pixel electrode 321 and a counter electrode 323 on the pixel electrode 321 that prevents an arc, etc., from occurring on the edge of the pixel electrode 321. The pixel-defining film 319 is formed of an organic insulating material, such as one or more of polyimide, polyamide, acrylic resin, benzocyclobutene, hexamethyldisiloxane (HMDSO), or phenolic resin, by using spin coating, etc.

In addition, a spacer is provided that prevents damage to the pixel-defining film 319 due to a mask. The spacer is integrally formed with the pixel-defining film 319. For example, the spacer and the pixel-defining film 319 are simultaneously formed in the same process by using a halftone mask process.

An emission layer 322b that corresponds to the pixel electrode 321 is disposed in the first opening OP1 in the pixel-defining film 319. The emission layer 322b includes a high molecular weight material or a low molecular weight material, and emits one of red light, green light, blue light, or white light.

An organic functional layer 322e is disposed on the pixel electrode 321 and the pixel-defining film 319, and is disposed over and/or under the emission layer 322b. In an embodiment, the organic functional layer 322e includes a first functional layer 322a and a second functional layer 322c. In an embodiment, one of the first functional layer 322a or the second functional layer 322c is omitted.

The first functional layer 322a is disposed under the emission layer 322b. The first functional layer 322a may have a single or multi-layer structure that includes an organic material. In an embodiment, the first functional layer 322a is a hole transport layer (HTL) that has a single-layer structure. In an embodiment, the first functional layer 322a includes a hole injection layer (HIL) and a hole transport layer (HTL). The first functional layer 322a is integrally formed and corresponds to the organic light-emitting diodes OLED in the display area DA.

The second functional layer 322c is disposed over the emission layer 322b. The second functional layer 322c may have a single or multi-layer structure including an organic material. The second functional layer 322c includes an at least one of an electron transport layer (ETL) or an electron injection layer (EIL). The second functional layer 322c is integrally formed and corresponds to the organic light-emitting diodes OLED in the display area DA.

The counter electrode 323 is disposed on the second functional layer 322c. The counter electrode 323 includes a conductive material that has a low work function. For example, the counter electrode 323 includes a (semi-)transparent layer that includes at least one of silver (Ag), magnesium (Mg), aluminum (Al), platinum (Pt), palladium (Pd), gold (Au), nickel (Ni), neodymium (Nd), iridium (Jr), chromium (Cr), lithium (Li), calcium (Ca), or an alloy thereof. Alternatively, the counter electrode 323 further includes a layer formed of one of ITO, IZO, ZnO, or In₂O₃ on the (semi)transparent layer that includes the above material. The counter electrode 323 is integrally formed and corresponds to the organic light-emitting diodes OLED included in the display area DA.

Layers from the pixel electrode 321 to the counter electrode 323 constitute the organic light-emitting diode OLED.

An upper layer 350 that includes an organic material is formed on the counter electrode 323. The upper layer 350 protects the counter electrode 323 and increases light extraction efficiency. In an embodiment, the upper layer 350 includes an organic material that has a refractive index higher than that of the counter electrode 323. In an embodiment, the upper layer 350 includes stacked layers that have different refractive indexes. For example, the upper layer 350 includes a high refractive index layer, a low refractive index layer, and a high refractive index layer that are sequentially stacked. For example, a refractive index of the high refractive index layer is equal to or greater than 1.7, and a refractive index of the low refractive index layer is equal to or less than 1.3.

In an embodiment, the upper layer 350 additionally includes LiF. In an embodiment, the upper layer 350 additionally includes an inorganic insulating material such as one of silicon oxide (SiO₂) or silicon nitride (SiNₓ). In an embodiment, the upper layer 350 is omitted. However, for convenience of explanation, the following will be described assuming that the upper layer 350 is disposed on the counter electrode 323.

FIG. 10 is a cross-sectional view of the display apparatus 1, according to an embodiment. In FIG. 10, the same members as those in FIG. 9 are denoted by the same reference numerals, and thus a repeated description thereof will be omitted.

Referring to FIG. 10, in an embodiment, a thin-film encapsulation layer 400 is disposed on the organic light-emitting diode OLED. The thin-film encapsulation layer 400 includes at least one inorganic layer and at least one organic layer. For example, the thin-film encapsulation layer 400 includes a first inorganic layer 410, an organic layer 420, and a second inorganic layer 430.

Each of the first inorganic layer 410 and the second inorganic layer 430 includes at least one inorganic insulating material. The inorganic insulating material is one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂).

The organic layer 420 includes a polymer-based material. Examples of the polymer-based material include an acrylic resin, an epoxy resin, polyimide, and polyethylene. For example, the organic layer 420 includes an acrylic resin such as polymethyl methacrylate or polyacrylic acid. The organic layer 420 can be formed by curing a monomer or applying a polymer.

The touch screen layer 500 is disposed on the thin-film encapsulation layer 400. The touch screen layer 500 includes a first conductive layer MTL1 and a second conductive layer MTL2 that includes a sensing electrode and/or a trace line. A first touch insulating layer 510 is disposed between the thin-film encapsulation layer 400 and the first conductive layer MTL1, and a second touch insulating layer 530 is disposed between the first conductive layer MTL1 and the second conductive layer MTL2.

Each of the first conductive layer MTL1 and the second conductive layer MTL2 includes a conductive material. The conductive material includes at least one of molybdenum (Mo), aluminum (Al), copper (Cu), or titanium (Ti), and may have a single or multi-layer structure that includes the above materials. In an embodiment, each of the first conductive layer MTL1 and the second conductive layer MTL2 has a (Ti/Al/Ti) structure in which a titanium layer, an aluminum layer, and a titanium layer are sequentially stacked.

Each of the first touch insulating layer 510 and the second touch insulating layer 530 includes an inorganic insulating material and/or an organic insulating material. The inorganic insulating material includes one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂) The organic insulating material includes one of an acrylic organic material or an imide-based organic material.

A filter plate 700 is an optical functional layer that is disposed on the touch screen layer 500. The filter plate 700 includes a black matrix 710, a color filter 720, and an overcoat layer 730.

The black matrix 710 is disposed in a non-emission area around the emission area EA, and surrounds the emission area EA. In an embodiment, the black matrix 710 passivates a touch electrode of the touch screen layer 500. For example, as shown in FIG. 10, the second conductive layer MTL2 of the touch screen layer 500 overlaps the black matrix 710, and the second conductive layer MTL2 is covered by the black matrix 710. The black matrix 710 includes an insulating material, such as an organic insulating material, that includes a black pigment or a black dye. The black matrix 710 includes a material that may also be included in the pixel-defining film 319.

The black matrix 710 includes a second opening OP2 that corresponds to the emission area EA. A size of the second opening OP2 in the black matrix 710 is equal to or greater than that of the first opening OP1 in the pixel-defining film 319.

The color filter 720 is disposed in the emission area EA of the organic light-emitting diode OLED. The color filter 720 include one of a red, green, or blue pigment or dye according to a color of light emitted by the organic light-emitting diode OLED.

The overcoat layer 730 is disposed on the black matrix 710 and the color filter 720 and covers and planarizes top surfaces of the black matrix 710 and the color filter 720.

In addition, in an embodiment, an optical functional layer that includes a polarizer, instead of the filter plate 700, is disposed on the touch screen layer 500. For example, the optical functional layer includes an anti-reflection layer. The anti-reflection layer reduces a reflectance of external light incident on the display apparatus 1.

In an embodiment, the anti-reflection layer is the polarizing film 110 (see FIG. 2). The polarizing film 110 includes a linear polarizer and a phase retardation film such as a quarter-wave (λ/4) film. The phase retardation film is disposed on the touch screen layer 500, and the linear polarizer is disposed on the phase retardation film. In an embodiment, the anti-reflection layer has a destructive interference structure. The destructive interference structure includes a first reflective layer and a second reflective layer that are located on different layers. First reflected light and second reflected light respectively reflected by the first reflective layer and the second reflective layer destructively interfere with each other, thereby reducing a reflectance of external light.

The cover window CW is disposed on the filter plate 700. The cover window CW is attached to the filter plate 700 by a sixth adhesive layer 27. For example, the sixth adhesive layer 27 may be a PSA or an optically clear adhesive (OCA).

In an embodiment, in the display apparatus 1 that includes the display area DA and the foldable area FA, because the digitizer 150 is disposed under the display panel 100, various input methods that use a pen, etc., can be provided to a user.

In addition, in an embodiment, because the foldable structure 145 that corresponds to the foldable area FA and is part of the first support member 140 disposed under the display panel 100, in-folding is more easily performed.

A battery is provided separately from a lower structure of the display apparatus 1. Because a volume of the battery is about twice a volume of a display module, there are limitations in designing the lower structure of the display apparatus 1.

Because the battery 170 is disposed in the lower structure of the display apparatus 1 and is embedded in the display module, designing the lower structure of the display apparatus 1 is easier. When the battery 170 provided in the display module functions as an auxiliary power supply, the display apparatus 1 can be used even in an emergency situation.

According to one or more embodiments, a display apparatus with increased performance is realized.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus, comprising:
a first display area, a second display area, and a foldable area disposed between the first display area and the second display area;
a display panel;
a first support member disposed under the display panel; and
a battery disposed under the first support member.

2. The display apparatus of claim 1, wherein the first support member comprises a first portion that at least partially overlaps the first display area, and a second portion that at least partially overlaps the second display area.

3. The display apparatus of claim 2, wherein the first support member further comprises a foldable structure disposed between the first portion and the second portion.

4. The display apparatus of claim 2, wherein the battery comprises a first battery that at least partially overlaps the first portion and a second battery that at least partially overlaps the second portion.

5. The display apparatus of claim 1, further comprising a heat dissipating layer disposed between the first support member and the battery.

6. The display apparatus of claim 5, wherein the heat dissipating layer comprises one of copper or graphite.

7. The display apparatus of claim 3, wherein an adhesive layer is disposed over or under the foldable structure.

8. The display apparatus of claim 7, wherein the adhesive layer comprises polyurethane.

9. The display apparatus of claim 1, wherein the battery is an auxiliary power supply.

10. The display apparatus of claim 1, wherein the battery is flexible.

11. The display apparatus of claim 10, wherein the battery includes a physically crosslinked organogel that is an active material or a separator of a positive electrode and a negative electrode of the battery.

12. The display apparatus of claim 1, wherein the battery is formed by using a printing method.

13. The display apparatus of claim 1, wherein the first support member comprises one of stainless steel, carbon fiber reinforced plastic, or glass fiber reinforced plastic.

14. The display apparatus of claim 1, wherein the first support member comprises one of an aluminum alloy, a titanium alloy, or a magnesium alloy.

15. The display apparatus of claim 1, further comprising a second support member disposed between the first support member and the battery.

16. The display apparatus of claim 1, further comprising a digitizer disposed between the first support member and the battery.

17. The display apparatus of claim 16, wherein the digitizer comprises a first digitizer that at least partially overlaps the first display area and a second digitizer that at least partially overlaps the second display area.

18. A rollable display apparatus, comprising:
a display panel;
a support member disposed under the display panel; and
a battery disposed under the support member,
wherein the battery is integrally formed with a display module of the rollable display apparatus.

19. The rollable display apparatus of claim 18, wherein the support member comprises a foldable structure.

20. A display apparatus, comprising:
a display panel;
a first support member disposed under the display panel, wherein the first support member comprises a first portion, a second portion, and a foldable structure disposed between the first portion and the second portion; and
a battery disposed under the first support member, wherein the battery comprises a first battery that at least partially overlaps the first portion and a second battery that at least partially overlaps the second portion.
